(19) United States
(12) Patent Application Publication
(10) Pub. No.: US 2015/0187597 A1
(43) Pub. Date: Jul. 2, 2015

(54) METHOD TO IMPROVE SLIP RESISTANCE OF SILICON WAFERS

(71) Applicant: Texas Instruments Incorporated, Dallas, TX (US)

(72) Inventors: Bradley David SUCHER, Murphy, TX (US); Rick L. WISE, Fairview, TX (US)

(21) Appl. No.: 14/576,617

(22) Filed: Dec. 19, 2014

Related U.S. Application Data
(60) Provisional application No. 61/922,138, filed on Dec. 31, 2013.

(51) Int. Cl. H01L 21/324; H01L 21/02

(52) U.S. Cl. CPC H01L 21/324; H01L 21/02664

(57) ABSTRACT

By controlling the concentration and size of bulk micro defects (BMD) during the manufacture of an integrated circuit slip and associated yield loss due to slip may be eliminated. A process for eliminating slip that is customized to an integrated circuit (IC) manufacturing flow is disclosed. The process is adapted to the oxygen content of the starting material and to the thermal budget of an IC manufacturing flow and generates a sufficient concentration of BMDs of a size that is optimized to getter microcracks thereby eliminating slip. Slip is eliminated in unpatterned wafers and in wafers containing shallow trench isolation and deep trench isolation using a BMD nucleation anneal and a BMD growth anneal.

### CROSS-REFERENCE TO RELATED APPLICATIONS

This application claims the benefit of priority under U.S.C. §119(e) of U.S. Provisional Application 61/922,138 (Texas Instruments docket number TI-68849, filed Dec. 31, 2013), the contents of which are hereby incorporated by reference.

### FIELD OF THE INVENTION

This invention relates to the field of integrated circuits. More particularly, this invention relates to the reduction of slip lines in large diameter wafers during high temperature processing.

### BACKGROUND OF THE INVENTION

Some integrated circuit process flows require high temperature manufacturing steps in the range of 1000° C. to 1250° C. for extended periods of times to form deep wells or to grow thick epitaxial layers. In addition rapid thermal processing steps may go up to 1250° C. or more especially in analog integrated circuit process flows. When wafers with diameters of 200 mm, 300 mm, or larger are subjected to these elevated temperatures, a common problem is for slip dislocations to form due to differential thermal stress across these large diameter wafers. The problem is exacerbated when these large diameter wafers have integrated circuit structures such as shallow trench isolation (STI) or deep trench isolation (DTI). Integrated circuit yield is degraded in regions where these slip dislocations occur.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to a more detailed description that is presented later.

A method of forming an integrated circuit comprises providing a wafer comprised of low resistance single crystal silicon substrate containing oxygen in the range of about 20 ppma to 30 pmma upon which a higher resistance single crystal material has been epitaxially grown. Prior to a thermal step that exceeds 1000° C., a BMD nucleation anneal is performed where the wafer is annealed in an inert or diluted oxygen atmosphere at temperature less than 800° C. A BMD growth anneal is performed where the wafer is annealed in an inert or diluted oxygen atmosphere at a temperature in the range of 800° C. to 1150° C.

### DESCRIPTION OF THE VIEWS OF THE DRAWING

FIG. 1 (Prior art) is a XRT image of wafer processed through a high temperature anneal without an embodiment BMD anneal.

FIG. 2 is a temperature versus time plot for an embodiment BMD anneal.

FIG. 3 is a XRT image of a wafer processed through a high temperature anneal with an embodiment BMD anneal

FIG. 4 is a flow diagram of steps in an embodiment BMD anneal.

### DETAILED DESCRIPTION OF EXAMPLE EMBODIMENTS

The present invention is described with reference to the attached figures, wherein like reference numerals are used throughout the figures to designate similar or equivalent elements. The figures are not drawn to scale and they are provided merely to illustrate the invention. Several aspects of the invention are described below with reference to example applications for illustration. It should be understood that numerous specific details, relationships, and methods are set forth to provide an understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

The preanneal conditions typically used to form BMDs for stress relaxation in IC substrates may not be sufficient to prevent slip during IC manufacturing. The preanneal conditions which suppress slip dislocations on lightly doped bulk silicon wafers grown by CZ may not be sufficient to suppress slip dislocations during the manufacture of integrated circuits on commonly used substrates such as lightly doped p-type epi (p− epi) on heavily p-doped bulk (p+ bulk) or lightly doped n-type epi (n− epi) on heavily doped n-type bulk (n+ bulk) silicon wafers. This is especially true for manufacturing flows that have thermal steps for extended times at high temperatures. Depending upon the temperature the BMDs may grow to a size where they generate rather than reduce slip or they may reduce to a size where they no longer prevent slip.

Preanneal conditions to suppress slip dislocations during manufacturing wafers become even more constrained when silicon structures with stress producing corners such as shallow trench isolation (STI) or deep trench isolation (DTI) are present on the wafer when it goes through high temperature, (>1000° C.) anneals commonly used to grow thick epi or to thermally drive deep diffusions for high voltage applications in IC manufacturing.

A process is described to insert a customized BMD nucleation and growth thermal steps near the beginning of an integrated circuit manufacturing flow. The customized BMD anneal takes into account the thermal budget of the integrated circuit manufacturing flow and provides a sufficient number of BMD's of the correct size to prevent slip. The BMD nucleation step takes into account the oxygen content of the IC substrate and provides greater than about 1E9/cm³ BMDs. Substrates with lower oxygen content may require a higher temperature and/or a longer time to nucleate a sufficient concentration of BMDs.

Typical wafer starting material is comprised of low resistivity single crystal epitaxial silicon grown on substrate with a higher resistivity. The high resistivity substrate may have in the range of about 20 ppma to 30 pmma oxygen in the wafer where greater than 50% of the oxygen is in the form of oxygen BMD's.

An embodiment BMD anneal is designed to nucleate a sufficient number of BMDs and to grow the BMDs to a sufficient size to prevent slip from occurring during the IC manufacturing process. The embodiment BMD anneal is designed to provide greater than about 1E9/cm³ BMDs with a size in the range of about 20 nn to 50 nm during the IC manufacturing processing.

The BMD nucleation anneal conditions depend upon the oxygen content of the starting material. The BMD nucleation anneal is preferably performed before any 1000 C anneal is performed in the integrated circuit (IC) manufacturing flow.

The BMD growth anneal conditions depend upon the thermal budget of the IC manufacturing flow. Too long of a anneal (BMD growth anneal plus IC manufacturing thermal anneals) at a temperature between about 800° C. and 1150° C. may grow the BMDs to a size that exacerbate slip (greater than about 200 nm) rather than alleviate slip. Too long of an anneal at a temperature above about 1150° C. may reduce the BMDs to a size that no longer contribute to slip reduction (less than about 20 nm).

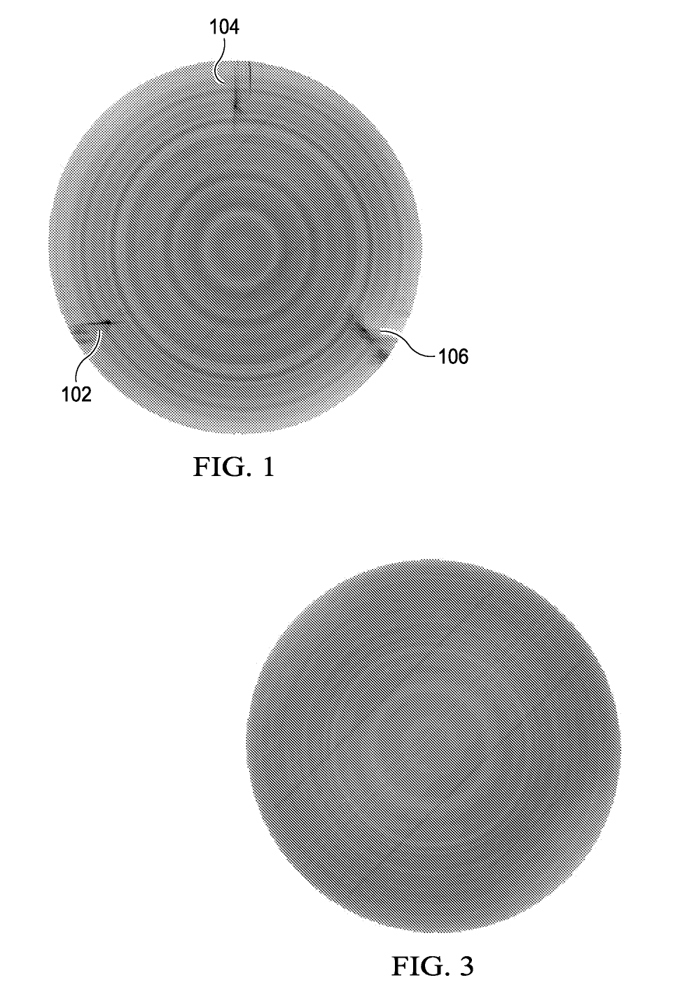

FIG. 1 shows a 300 mm lightly doped p-type epi (p− epi) on heavily doped p-type wafer (p+ wafer) that was that has been processed through a 1200° C. deep n-well anneal without an embodiment BMD anneal. Slip lines 102, 104, and 106 extend several millimeters into the wafer. Die in areas with slip lines typically do not yield.

The embodiment BMD anneal process consists of a BMD nucleation anneal step followed by one or more BMD growth anneal steps.

The BMD nucleation step may be performed in an inert atmosphere such as nitrogen or argon or in a diluted oxygen ambient (nitrogen plus <10% oxygen) for a time in the range of about 0.5 to 3 hours and a temperature in the range of about 550° C. to 750° C. If the nucleation step is performed at a temperature higher than about 750° C., the nucleation density may be insufficient to prevent slip dislocations. An oxygen BMD density of about 1E9/cm³ or greater is desired. For wafers with an oxygen content at the lower end of the specification a temperature at the higher end of the temperature range may be used or a time at the higher end of the time range may be used to enable more oxygen diffusion to take place to nucleate the desired number of BMD's.

The BMD growth step may be performed at a temperature in the range of about 800° C. to 1150° C. in an inert ambient such as nitrogen or argon or in a diluted oxygen ambient (nitrogen plus <10% oxygen). The length of time for BMD growth depends upon the oxygen content of the wafer and thermal budget of the integrated circuit manufacturing process. It is desirable for the size of the BMDs to be in the range of about 20 nm to 50 nm. If the size of the BMDs is less than about 20 nm, they are no longer effective as termination sites for slip dislocations. Above about 1150° C. the oxygen BMD's decrease in size and dissolve over time. If subsequent processing steps are at or below 1150° C., the BMD growth anneal time may be shortened to account for the additional oxygen BMD growth that may occur during the subsequent manufacturing steps. If, however, subsequent manufacturing steps are with temperatures at or above 1150° C., the BMD growth anneal time may be increased to account for BMD size reduction that will later occur during the greater than 1150° C. anneal. If the BMD's are allowed to grow too large (greater than about 200 nm) they become sources of slip dislocations instead of termination sites for slip dislocations. Another consideration in determining the embodiment anneal conditions is to not convert more than about 70% of the interstitial oxygen to BMD's. An interstitial oxygen content lower than about 10 ppma significantly weakens the single crystal silicon wafer.

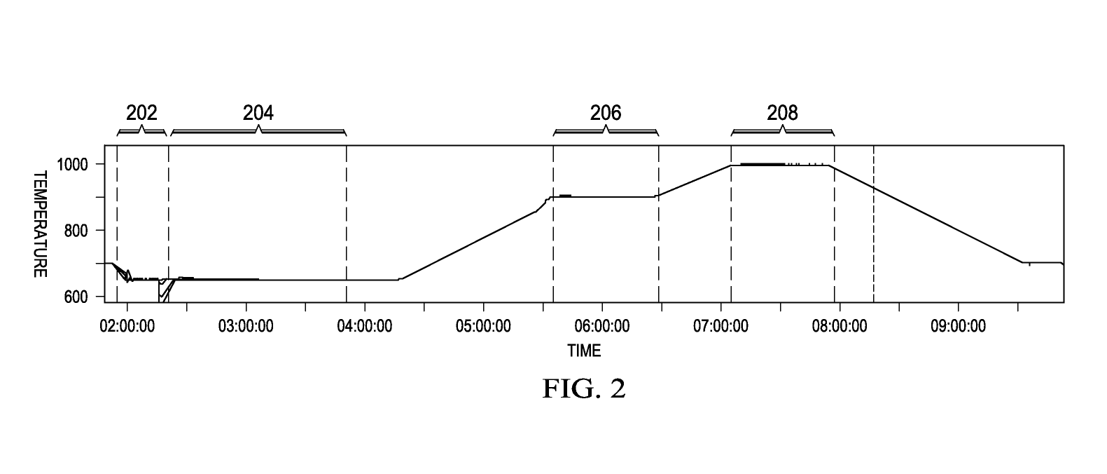

In an illustrative example of an embodiment BMD anneal is shown in FIG. 2. The starting material is p− epi (10-15 ohm-cm) on p+ (0.01-0.02 ohm-cm) substrates with an oxygen concentration of 27+/−3 ppma. The IC wafers are loaded in a furnace at about 650° C. during step 202. The loading step 202 is followed by a BMD nucleation anneal step 204 at 650° C. for 120 minutes in diluted oxygen (<10% oxygen in nitrogen). The BMD nucleation step 204 is followed by a first BMD growth anneal step 206 at about 900° C. for 60 minutes in diluted oxygen (<10% oxygen in nitrogen). The first BMD growth anneal step 206 is followed by a second BMD growth anneal step 208, at about 1000° C. for 60 minutes in diluted oxygen (<10% oxygen in nitrogen). In the example embodiment the growth step is divided into a first 900° C. step followed by a second 1000° C. step to reduce the processing time. A one step anneal for a longer time at 900° C. may also be used.

FIG. 3 shows an IC wafer process according to the embodiment BMD anneal described in FIG. 2. Unlike the wafer in FIG. 1 which was processed without the embodiment BMD anneal, there are no slip lines in this wafer.

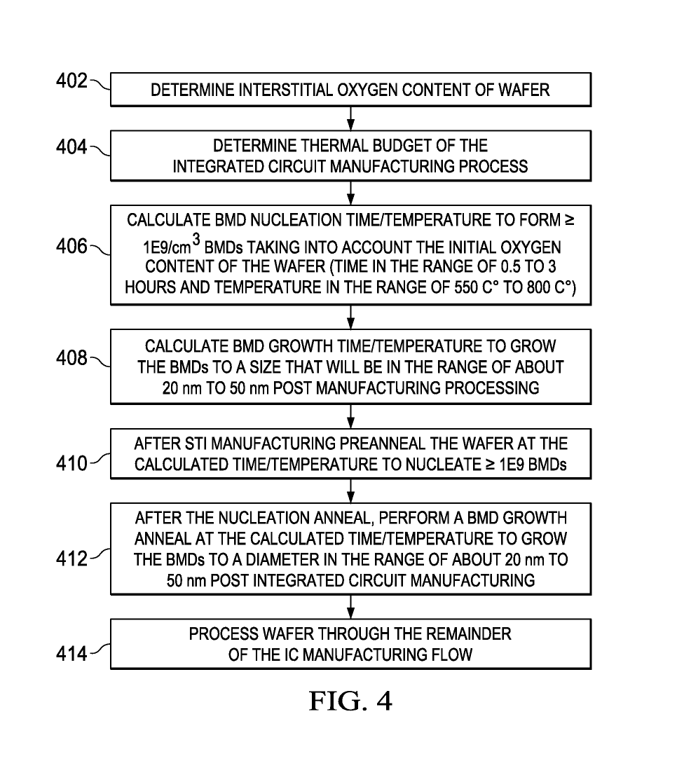

A flow diagram of the embodiment BMD anneal process is described in the flow diagram in FIG. 4.

In the first step 402 the oxygen content of the wafer is determined.

In step 404 the thermal budget of the manufacturing flow of the integrated circuit is determined.

In step 406 a BMD nucleation anneal time and temperature that will nucleate greater than about 1E9/cm³ BMDs is determined. The time and temperature is based upon the initial oxygen content of the wafer. If the oxygen content is low a time and/or temperature in the higher end of the range may be needed. The time is typically in the range of about 0.5 to 3 hours and the temperature is in the range of about 550° C. to 800° C.

In step 408 a BMD growth time and temperature is determined based upon the thermal budget of the manufacturing flow that was determined in step 404. The BMD growth may be performed in an inert atmosphere such as nitrogen or argon or may be performed in diluted oxygen (nitrogen plus <10% oxygen). The temperature is in the range of about 800° C. to 1150° C. If there is a long anneal in the manufacturing flow such as a tank drive for an hour or more at a temperature in the range of about 800° C. to 1100° C., a shorter time and/or a lower temperature may be used to account for the BMD growth that will take place during the long anneal. If there is an anneal in the manufacturing flow with a temperature that exceeds 1150° C., a longer time may be used to grow the BMDs to a size greater than about 50 nm to account for the size reduction that will occur during the greater than 1150° C. anneal.

In step 410 the BMD nucleation anneal is performed to form greater than or equal to 1E09/cm³ BMDs. The BMD nucleation anneal is performed before the substrate sees an anneal greater than about 1000° C. Preferably approximately 1E11/cm³ BMDs may be formed.

In step 412 a BMD growth anneal is performed to grow the BMD's to a size that is compatible with the thermal budget of the manufacturing flow. The BMD anneal may be performed with shallow trench isolation and with deep trench isolation geometries present.

In step 414 the integrated circuit (IC) wafer is processed through the remaining process steps in the manufacturing flow. The embodiment BMD stress anneal is designed so that post processing greater than about 1E09/cm³ BMDs and greater than about 10 ppma interstitial oxygen atoms remain in the substrate wafer of the integrated circuit.

While various embodiments of the present invention have been described above, it should be understood that they have been presented by way of example only and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. A method of forming an integrated circuit, comprising the steps:
providing a wafer comprised of low resistance single crystal silicon substrate containing oxygen in the range of 20 ppma to 30 pmma upon which a higher resistance single crystal material has been epitaxially grown;
prior to a thermal step that exceeds 1000° C., performing a BMD nucleation anneal where said wafer is annealed in an inert or diluted oxygen atmosphere at temperature less than 800° C.; and
performing an BMD growth anneal where the wafer is annealed in an inert or diluted oxygen atmosphere at a temperature in the range of 800° C. to 1150° C.

2. The method of claim 1, wherein a time and temperature of the BMD nucleation anneal is based upon the oxygen content of the wafer and produces at least 1E9/cm³ BMDs.

3. The method of claim 1, wherein a time and temperature of the BMD growth anneal is based upon subsequent thermal cycles in a manufacturing flow of the integrated circuit and produces BMDs with a size in the range of 20 nm to 50 nm after the integrated circuit manufacturing is complete.

4. The method of claim 1, wherein the low resistance single crystal silicon substrate is a 0.01 to 0.02 ohm-cm p-type substrate containing 20 to 30 pmma interstitial oxygen and the high resistance single crystal material is 10-15 ohm-cm p− epi.

5. The method of claim 1, wherein the BMD nucleation anneal is a 0.5 to 3 hour anneal in an inert atmosphere or a diluted oxygen atmosphere at a temperature of 550° C. to 750° C.

6. The method of claim 5, wherein the BMD nucleation anneal is a 2 hour anneal at 700° C.

7. The method of claim 5, wherein the diluted oxygen atmosphere is nitrogen with less than 10% oxygen.

8. The method of claim 1, wherein the wafer contains shallow trench isolation.

9. The method of claim 1, wherein the wafer contains shallow trench isolation and deep trench isolation.

10. The method of claim 1, wherein the BMD growth anneal is a one step anneal for 0.5 to 16 hours.

11. The method of claim 1, wherein the BMD growth anneal is a multistep growth anneal where a first BMD growth anneal is performed at a temperature that is lower than a subsequent BMD growth anneal.

12. The method of claim 11, wherein the multistep growth step is an anneal for one hour at 900° C. plus an anneal at 1000° C. for one hour.

13. The method of claim 1, wherein the step of nucleating BMDs, nucleates at least 1E09 BMDs per cubic centimeter.

14. The method of claim 1, wherein the step of nucleating BMDs, nucleates 1E11 BMDs per cubic centimeter.

15. The method of claim 1, wherein the inert atmosphere is nitrogen, helium, or argon.
